(19) United States
(12) Patent Application Publication
(10) Pub. No.: US 2002/0179984 A1
(43) Pub. Date: Dec. 5, 2002

(54) Silicon-based ferroelectric cantilever structure

(76) Inventors: Tian-Ling Ren, Beijing (CN); Lin-Tao Zhang, Beijing (CN); Zhi-Jian Li, Beijing (CN); Li-Tian Liu, Beijing (CN)

Correspondence Address: J.C. Patents, Inc., 4 Venture, Suite 250, Irvine, CA, 92618, US

(21) Appl. No.: 09/871,391

(22) Filed: May 31, 2001

(51) Int. Cl. H01L 29/84

(52) U.S. Cl. 257/416

(57) ABSTRACT

A structure of a cantilever is disclosed. A semiconductor substrate is provided. A first support layer is formed over a semiconductor substrate. A second support layer is formed over the first support layer. A thin first and second conductive films are sequentially formed over the substrate. The first and the second conductive films form a lower electrode. A ferroelectric film is formed over the lower electrode. A third and fourth conductive films are sequentially formed over the ferroelectric film. The third and the fourth conductive layer form the upper electrode. The resulting structure is annealed.

### BACKGROUND OF THE INVENTION

1. Filed of Invention

The present invention relates generally to semiconductors and more specifically to a cantilever structure.

2. Description of Related Art

Microphones and microspeakers are very important acoustic devices and have wide applications in multimedia, mobile communications and military fields. Of the conventional microphones, the chief disadvantages are large column and high cost. Recently, micromachining process, integrated with silicon technology, was used in the fabrication of microphone to reduce the column and cost of the microphone.

It is well known that microphones are basically pressure sensors that detect airborne sound pressures that are ten orders of magnitude lower than the ambient pressure. As it is well known that ferroelectric materials for their electromechanical coupling properties. When electric field is applied across the ferroelectric layer, the ferroelectric cantilever structure will be deflected. Then the cantilever compresses the ambient air to produce the output sound pressures due to its deflection. This is the function of a microspeaker, which transforms the electrical signal to sound. On the other hand, the deflection of the ferroelectric thin film will produce extra electric charges on the surface of the thin film. When the vibration of the ambient air or sound produces deflection, the electric signal appears across the thin film. This is the function of a microphone, which transforms a sound signal into an electric signal. Thus sensitivity becomes an important property for these devices. However, the micromachined microphones usually have got low sentivities due to their fabrication process and structures.

Ferroelectric materials are a well known material because of their remarkable dielectric, peizoelectric, ferroelectric and photoelectric properties. In the 1980s, the first micromachined microphone was realized on the silicon wafer using the peizoelectric ZnO materials. In this device, the sputtered peizoelectric ZnO layer transforms the mechanical deflection of an etched Si diaphragm into a peizoelectric charge. In 1996, a ZnO-based cantilever structure was presented by S. S. Lee, R. P. Reid and M. White. According to them, peizoelectric cantilever structure produces a microphone with sensitivity greater than other previously reported microphones. And when the device is driven by an electric field, the device can also act as a microspeaker to produce acoustic output.

In the transformation from an electrical signal into a sound signal, one of the key factors is the peizoelectric constant (d₃₁). As the d₃₁ value of the peizoelectric material increases, the deflection or the electric signal increases. Therefore, the selection of the materials having higher d₃₁ values can substantially improve the sensitivity and the output sound pressure of the integrated microphone and microspeaker. Even though such a design rule is well known given the complexity integrating these materials and their manufacturing process, and even their use becomes less attractive when cost and size are critical.

Accordingly, the present invention provides a cantilever structure using ferroelectric thin films having higher peizoelectric constant compared to ZnO, so that the sensitivity and the output sound pressure can be further increased.

### SUMMARY OF THE INVENTION

The present invention provides a cantilever structure including a ferroelectric material to substantially improve the sensitivity of the cantilever.

The present invention provides a structure using a ferroelectric material for improving the quality of the integrated microphone and microspeaker.

The present invention provides a simple, compliant, and cost effective cantilever structure having improved sensitivity and higher output sound pressure compared to the conventional cantilever.

The present invention provides a cantilever structure in which ferroelectric materials, such as lead zirconate titanate [PZT.Pb(Zr.Ti).O₃], doped PZT, PbMg_{1/3}.Nb_{2/3}.O₃-Pb.TiO₃ (PMN-PT) are integrated into microphone and microspeaker to improve the sensitivity and the output sound pressure of the integrated microphone and microspeaker.

Accordingly the present invention provides a cantilever structure comprising, a semiconductor substrate. A first support layer is formed over a semiconductor substrate. A second support layer is formed over the first support layer. A thin first and second conductive films are sequentially formed over the substrate. The first and the second conductive films form a lower electrode. A ferroelectric film is formed over the lower electrode. A third and fourth conductive films are sequentially formed over the ferroelectric film. The third and the fourth conductive layer form the upper electrode. A slot is formed at a predetermined region. The resulting structure is annealed.

It is to be understood by those skilled in the art that because the peizoelectric constant of the ferroelectric materials such as PZT, doped PZT and PMN-PT, is higher compared to ZnO material, therefore by integrating the said ferroelectric films in a cantilever and integrating it into a microphone and microspeaker, the sensitivity and the output sound pressure of the integrated microphone and microspeaker can be further increased.

It is to be further understood by those skilled in the art that the present invention provides a simple, compliant, and cost effective cantilever structure having improved sensitivity and higher output sound pressure compared to the conventional cantilever.

### BRIEF DESCRIPTION OF THE DRAWINGS

FIG. 1 shows a schematic, top sectional view showing the structure of a cantilever in accordance with the present invention.

FIG. 2 shows a schematic, cross sectional view along the line I-I as shown in FIG. 1, showing the structure of a cantilever in accordance with the present invention.

### DESCRIPTION OF THE PREFERRED EMBODIMENTS

Reference will be made in detail to the present preferred embodiments of the invention, examples of which are illustrated in the accompanying drawings. Wherever possible, the same reference numbers are used in the drawings and the description to refer to the same or like parts.

It is to be understood that the foregoing general description and the following detailed description are exemplary, and are intended to provide further explanation of the invention as claimed.

In the present invention, a new cantilever structure, in which the ZnO layer is replaced by ferroelectric material such as PZT thereof.

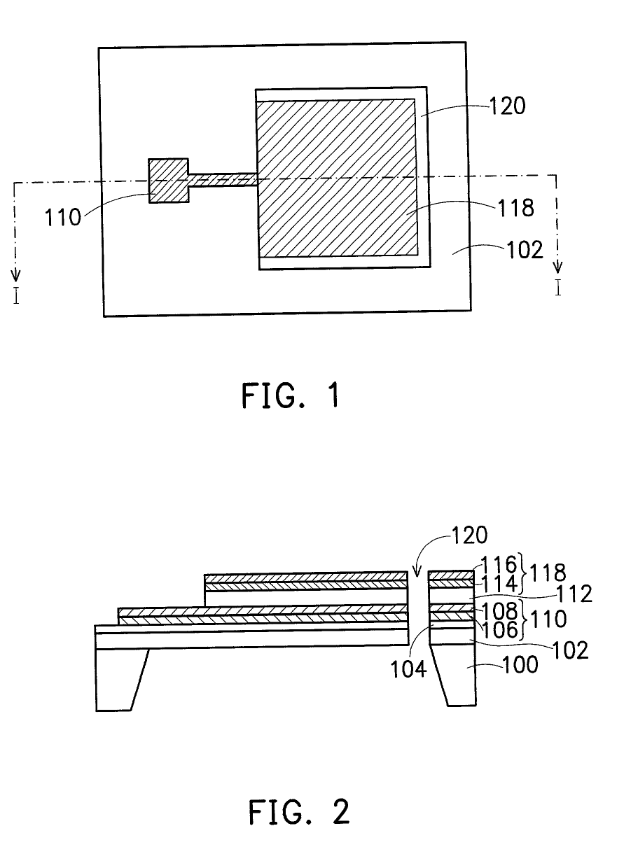

FIG. 1 shows a schematic, top sectional view showing the structure of a cantilever in accordance with the present invention.

FIG. 2 shows a schematic, cross sectional view showing the structure of a cantilever in accordance with the present invention.

According to the preferred embodiment of the present invention, a semiconductor substrate 100, as shown in FIG. 1 and 2, is provided. The semiconductor substrate 100 is preferably made of silicon material, other materials such as glass or metal may also be used. A first support layer 102 as shown in FIG. 2 (not shown in FIG. 1) is formed over a semiconductor substrate 100. The first support layer 102 is preferably made of silicon nitride material formed by performing a conventional deposition technique such as a low pressure chemical vapor deposition method (LPCVD). The thickness of the first support layer 102 is preferably within a range of about 0.5-2.0 μm. A second support layer 104 as shown in FIG. 1 and 2, is formed over the first support layer 102. The second support layer 104 is preferably made of silicon dioxide material formed by performing a conventional deposition technique such as a chemical vapor deposition method. The thickness of the dielectric layer 104 is preferably within a range of about 0.1-0.5 μm.

A thin first conductive film 106 as shown in FIG. 2 (not shown in FIG. 1), is formed over the second support layer 104. The first conductive film 106 preferably comprises a Ti material. The first conductive film 106 is preferably formed by performing a sputtering process. The thickness of the first conductive layer 106 is preferably within a range of 0.05-1.5 μm. A thin second conductive film 108, as shown in FIG. 1 and 2, is formed over the first conductive layer 106. The second conductive layer 108 preferably comprises a Pt material. The second conductive layer 108 is preferably formed by performing a sputtering process. The thickness of the second conductive layer 108 is preferably within a range of 0.005-0.05 μm. The first and second conductive layers 106 and 108 form the lower electrode 110 of the cantilever structure as shown in FIG. 1 and 2.

A thin ferroelectric film 112 as shown in FIG. 2 (not shown in FIG. 1) is spin coated over the slower electrode 110. The ferroelectric film 112 is preferably selected from a group consisting of PZT, doped PZT, and PMN-PT material thereof. The PZT material preferably having a composition of Pbₓ(Zr_{y}Ti_{1-y})O₃ wherein x=0.9-1.1, y=0.4-0.6. The ferroelectric film 112 is preferably formed by performing a sol-gel deposition method. The ferroelectric film 112 is spun coated over the lower electrode 110 and dried by heating at 200° C. over a hot plate for 1 minute. Then the substrate 100 is heated at 600° C. for 2 minutes in a tube oven to remove impurities such as organic residues. A final annealing process is preferably carried out at a temperature of about 650-750° C. for a duration of about 30-45 minutes. After the final annealing process, the ferroelectric film 112 is transformed from an amorphous state to a stable well crystallized perovskite state. The thickness of the ferroelectric film 112 is preferably within a range of 0.5-2.0 μm.

A thin third conductive film 114 as shown in FIG. 2 (not shown in FIG. 1), is formed over the ferroelectric film 112. The third conductive film 114 preferably comprises a Ti material. The third conductive film 114 is preferably formed by performing a sputtering process. The thickness of the third conductive film 114 is preferably within a range of 0.05-0.1 μm. A thin fourth conductive film 116, as shown in FIG. 2 (not shown in FIG. 1), is formed over the conductive film 112. The fourth conductive film 116 preferably comprises a Pt material. The fourth conductive film 116 is preferably formed by performing a sputtering process. The thickness of the fourth conductive film 116 is preferably within a range of 0.005-0.01 μm. The third and fourth conductive layers 114 and 116 forms the upper electrode 118 of the cantilever structure as shown in FIG. 1 and 2.

A slot 120, as shown in FIG. 1 and 2, is formed in a predetermined region by selectively etching the upper electrode 118, ferroelectric film 112, the lower electrode 110, and the second and first support layers 102 and 104. Removing a portion of the upper electrode 118, the ferroelectric film 112 and the lower electrode 110.

A cantilever structure 150 is thus formed. The length and the width of cantilever are 500-2000 μm. In summary, the thickness of Si₃N₄ is 0.5-2 μm. The thickness of SiO₂ is 3000-5000 Å. The Pt and Ti layer in the electrodes are 500-1000 angstroms and 50-100 Å respectively. The thickness of PZT layer is 0.5-2 μm and the composition of PZT is Pbₓ(Zr_{y}Ti_{1-y})O₃ wherein x=0.9-1.1, y=0.4-0.6.

It is to be understood by those skilled in the art that because the peizoelectric constant of the ferroelectric materials such as PZT, doped PZT, and PMN-PT is higher compared to ZnO material, therefore by including the said ferroelectric films in a cantilever and integrated into a microphone and microspeaker, the sensitivity and the output sound pressure of the integrated microphone and microspeaker can be further increased.

It is to be further understood by those skilled in the art that the present invention provides a simple, compliant and cost effective process for fabricating a cantilever having improved sensitivity and higher output sound pressure compared to the conventional cantilever.

The sensitivity and the output sound pressure were stimulated theoretically to show the effect of the improved cantilever structure. The simulation results of three cantilever structures examples according to the present invention are listed below.

### EXAMPLE 1

The thickness of the layers in the Pt/Ti/PZT/Pt/Ti/SiO₂/Si₃N₄ cantilever structure is in the order of 0.05/0.005/1.0/0.05/0.005/0.5/1.0 μm, the length and width of the cantilever are both 1000 μm. The output sound pressure levels of the microspeaker at the first and second resonant frequencies are 65 dB and 99 dB respectively. The sensitivity of the microphone is 0.8 mV/μbar at low frequency. As a comparison, a similar cantilever structure using ZnO as the piezoelectric layer is also simulated. The output sound pressure levels of the microspeaker at the first and second resonant frequencies are 46 dB and 73 dB respectively. The sensitivity of the microphone is 0.7 mV/μbar at low frequency.

### EXAMPLE 2

The thickness of the layers in the Pt/Ti/PZT/Pt/Ti/SiO₂/Si₃N₄ cantilever structure is in the order of 0.08/0.008/1.5/0.08/0.008/0.4/1.8 μm, the length and width of the cantilever are both 1500 μm. The output sound pressure levels of the microspeaker at the first and second resonant frequencies are 64 dB and 96 dB respectively. The sensitivity of the microphone is 1.3 mV/μbar at low frequency. As a comparison, a similar cantilever structure using ZnO as the piezoelectric layer is also simulated. The output sound pressure levels of the microspeaker at the first and second resonant frequencies are 43 dB and 82 dB respectively. The sensitivity of the microphone is 1.1 mV/μbar at low frequency.

### EXAMPLE 3

According to the third preferred embodiment of the present invention, the thickness of the layers in the Pt/Ti/PZT/Pt/Ti/SiO₂/Si₃N₄ cantilever structure is in the order of 0.1/0.01/0.5/0.1/0.01/0.3/0.5 μm, the length and width of the cantilever are both 2000 μm. The output sound pressure levels of the microspeaker at the first and second resonant frequencies are 63 dB and 102 dB respectively. The sensitivity of the microphone is 1.7 mV/μbar at low frequency. As a comparison, a similar cantilever structure using ZnO as the piezoelectric layer is also simulated. The output sound pressure levels of the microspeaker at the first and second resonant frequencies are 42 dB and 72 dB respectively. The sensitivity of the microphone is 1.5 mV/μbar at low frequency.

CONCLUSION: The sensitivity and the output sound pressure level of the cantilever are increased by including the PZT material.

While the best mode utilizes the above of specific thickness of Pt/Ti/PZT/Pt/Ti/SiO₂/Si₃N₄ cantilever structure, however it should be understood by those skilled in the art that the present invention is applicable to cantilever structures with Pt/Ti/PZT/Pt/Ti/SiO₂/Si₃N₄ layers of different thickness and different composition of PZT thereof, may be used to practice the present invention.

It is to be understood by those skilled in the art that the thickness of each layer in the cantilever is designed based on the analysis of the sensitivity and sound output pressure. The aim of the design is to further enlarge the sensitivity and output sound pressure level without affecting the structure firmness. The design parameters of each layer is as below. The length and the width of cantilever are 500-2000 μm. In summary, the thickness of Si₃N₄ is 0.5-2 μm. The thickness of SiO₂ is 3000-5000 Å. The Pt and Ti layer in the electrodes are 500-1000 Å and 50-100 Å respectively. The thickness of PZT layer is 0.5-2 μm and the composition of PZT is Pbₓ(Zr_{y}Ti_{1-y})O₃ wherein x=0.9-1.1, y=0.4-0.6. Therefore the present invention provides a simple, compliant design parameters. Because the present invention shows a sol-gel process for forming the thin ferroelectric film, the manufacturing process can be simplified and the cost of fabrication is substantially reduced.

While the invention has been described in conjunction with a specific best mode, it is to be understood that many alternatives, modifications, and variations will be apparent to those skilled in the art in light of the a foregoing description. Accordingly, it is intended to embrace all such alternatives, modifications, and variations which fall within the spirit and scope of the included claims. All matters set forth herein or shown in the accompanying drawings are to be interpreted in an illustrative and non-limiting sense.

What is claimed is:

1. A cantilever structure for integrated microphone and microspeaker, the structure comprising:
a semiconductor substrate;
a first support layer formed over the substrate;
a second support layer formed over the first support layer;
a first conductive film formed over the second support layer;
a second conductive film formed over the first conductive film, wherein the first and the second conductive films serves as a lower electrode;
a ferroelectric film formed over the lower electrode;
the resulting structure annealed;
a third conductive film formed over the ferroelectric film; and
a fourth conductive film formed over the third conductive film.

2. The structure according to claim 1, wherein the material of the ferroelectric film includes a PZT thereof.

3. The structure according to claim 1, wherein the ferroelectric film comprises a PZT film.

4. The structure according to claim 3, wherein the composition of the PZT film include Pbₓ(Zr_{y}Ti_{1-y})O₃ wherein x=0.9-1.1, y=0.4-0.6.

5. The structure according to claim 1, wherein the thickness of the ferroelectric film is within a range of 0.5 to 2.0 μm.

6. The structure according to claim 1, wherein the ferroelectric film is formed by performing a sol-gel deposition process.

7. The structure according to claim 1, wherein the annealing process is performed at a temperature of 650-750° C. for a duration of 30-45 minutes, wherein the ferroelectric film is transformed from an amorphous form to a stable well crystallized perovskite form.

8. The structure according to claim 1, wherein the first and the third conductive film comprises a Ti film.

9. The structure according to claim 1, wherein the second and fourth conductive film comprises a Pt film.

10. The structure according to claim 1, wherein the thickness of the first, second, third and fourth conductive films are within a range of 0.05-1.50 μm, 0.005-0.05 μm, 0.05-0.10 μm, and 0.005-0.01 μm, respectively.

11. The structure according to claim 1, wherein the thickness of the first and the second support layer is within a range of 0.5-2.0 μm and 0.10-0.50 μm respectively.

12. The structure according to claim 1, wherein the material of the substrate is selected from a group consisting of silicon, glass and metal.
